(19) United States
(12) Patent Application Publication
(10) Pub. No.: US 2025/0208226 A1
(43) Pub. Date: Jun. 26, 2025

(54) APPARATUS FOR DIAGNOSING ABNORMALITY IN BATTERY CELL AND METHOD THEREOF

(71) Applicants: Hyundai Motor Company, Seoul (KR); Kia Corporation, Seoul (KR)

(72) Inventors: Hyun Jun JANG, Daegu (KR); Min Jun PARK, Hwaseong-Si (KR); Woo Sung KIM, Suwon-Si (KR); Tae Kyu KANG, Suwon-Si (KR)

(73) Assignees: Hyundai Motor Company, Seoul (KR); Kia Corporation, Seoul (KR)

(21) Appl. No.: 18/737,741

(22) Filed: Jun. 7, 2024

(30) Foreign Application Priority Data
Dec. 20, 2023 (KR) 10-2023-0187381

(51) Int. Cl. G01R 31/392; G01R 31/3842; G01R 31/396

(52) U.S. Cl. CPC G01R 31/392; G01R 31/3842; G01R 31/396

(57) ABSTRACT

In an apparatus for diagnosing an abnormality of a battery cell and a method thereof, the apparatus generates a voltage profile of each battery cell while the vehicle is driven, converts the voltage profile of each battery cell from a time domain to a frequency domain, determines a frequency coefficient of each battery cell, and diagnoses an abnormality in each battery cell based on relative comparison values of the frequency coefficients between the battery cells, preventing thermal runaway of the battery cell in advance while driving a vehicle.

### CROSS-REFERENCE TO RELATED APPLICATION

The present application claims priority to Korean Patent Application No. 10-2023-0187381, filed on Dec. 20, 2023, the entire contents of which is incorporated herein for all purposes by this reference.

BACKGROUND OF THE PRESENT DISCLOSURE

### FIELD OF THE PRESENT DISCLOSURE

The present disclosure relates to a technology for diagnosing an abnormality in a battery cell based on a voltage profile in the frequency domain.

### DESCRIPTION OF RELATED ART

In general, an electric vehicle, which is a vehicle driven by electrical energy, is provided with a battery including a plurality of battery cells that store electrical energy. In the instant case, the battery cell includes a positive electrode current collector, a negative electrode current collector, a separator, an active material, an electrolyte, and the like, and may be repeatedly charged and discharged through electrochemical reactions between components. In the instant case, to protect the plurality of battery cells from external shocks such as heat, vibration, and the like, a battery module may be formed by combining the plurality of battery cells into one. To systematically manage a plurality of battery modules, a battery pack (i.e., a battery system) may be formed by use of the plurality of battery modules, a battery management system (BMS), and a cooling device.

Because an electric vehicle is driven using electrical energy stored in a battery as a power source, the performance of the vehicle is determined by the performance of the battery. Therefore, to improve the performance of an electric vehicle, it is required to manage the battery to maximize the performance of the battery.

In recent years, because battery cells with excellent performance are used to improve the power source of a vehicle, and the number of battery cells increases gradually, it is more required to manage a battery. Such battery management is generally performed by a battery management system (BMS).

The battery management system measures cell state information including a voltage, a current, a temperature, and the like of a battery cell from a battery module provided in an electric vehicle, utilizes the cell state information and option values for controlling battery cells to manage the charging and the discharging of the battery cells, and performs cell balancing to maintain balance between the battery cells. In the instant case, the cell balancing is one of the control operations of a battery management system that equalizes the voltages or charge amounts of battery cells. Furthermore, each battery cell of a battery module may have differences in electrical characteristics even when the battery cells are manufactured under the same manufacturing conditions and environment, and may also have differences in electrical characteristics even when the battery cells are mounted and operated in an electric vehicle.

Due to such differences in electrical characteristics, even when battery cells are charged and discharged with the same current, voltage imbalance or residual charge imbalance may occur between interconnected battery cells, and the voltage imbalance or residual charge imbalance between battery cells may cause the available voltage range of battery cells to decrease or the charging and discharging cycle to be shorter.

Meanwhile, because a plurality of battery cells are connected to each other in series and parallel in one battery, when thermal runaway occurs in one battery cell, micro short circuit (MSC) or internal short circuit (ISC) may be caused by the lithium plating phenomenon and lead to thermal runaway of the entire battery.

Therefore, there is a need to provide an active diagnosis technology through an electrochemical behavior analysis of a battery cell while a vehicle is driven.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus for diagnosing an abnormality of a battery cell configured for preventing thermal runaway of the battery cell in advance while driving a vehicle by generating a voltage profile of each battery cell while the vehicle is driven, converting the voltage profile of each battery cell from a time domain to a frequency domain, determining a frequency coefficient of each battery cell, and diagnosing an abnormality in each battery cell based on relative comparison values of the frequency coefficients between the battery cells.

Another aspect of the present disclosure provides an apparatus for diagnosing an abnormality of a battery cell configured for preventing thermal runaway of the battery cell in advance while driving a vehicle by generating a voltage profile of each battery cell while the vehicle is driven, converting the voltage profile of each battery cell from a time domain to a frequency domain, determining relative comparison values for frequency coefficients of each battery cell, and diagnosing that an abnormality occurs in the battery cell of which the relative comparison value exceeds a threshold.

Yet another aspect of the present disclosure provides an apparatus for diagnosing an abnormality of a battery cell configured for preventing thermal runaway of the battery cell in advance while driving a vehicle by repeatedly generating a voltage profile of each battery cell while the vehicle is driven, converting the voltage profile of each battery cell from a time domain to a frequency domain, determining relative comparison values for frequency coefficients of each battery cell, and diagnosing that an abnormality occurs in the battery cell 210 detected as the number of relative comparison values exceeding a threshold exceeds a preset number of times.

Yet another aspect of the present disclosure provides an apparatus for diagnosing an abnormality of a battery cell configured for preventing thermal runaway of the battery cell in advance while driving a vehicle by generating a voltage profile of each battery cell every time the vehicle is driven, converting the voltage profile of each battery cell from a time domain to a frequency domain, determining relative comparison values for frequency coefficients of each battery cell, recording an identification number of a battery cell corresponding to the maximum value among relative comparison values and an identification number of a battery cell corresponding to the minimum value among relative comparison values, and diagnosing that an abnormality occurs in a battery cell with an identification number recorded in excess of a preset number of times.

Yet another aspect of the present disclosure provides an apparatus for diagnosing an abnormality of a battery cell configured for preventing thermal runaway of the battery cell in advance while driving a vehicle by generating a current profile and a voltage profile of each battery cell while the vehicle is driven, determining whether a high-frequency component is included in the voltage profile in the frequency domain based on the current profile, converting the voltage profile of each battery cell from a time domain to a frequency domain when it is determined that the voltage profile in the frequency domain includes a high-frequency component, determining frequency coefficients of each battery cell, and diagnosing an abnormality in each battery cell based on relative comparison values of the frequency coefficients between the battery cells.

Yet another aspect of the present disclosure provides an apparatus for diagnosing an abnormality of a battery cell configured for preventing thermal runaway of the battery cell in advance while driving a vehicle by generating a current profile and a voltage profile of each battery cell while the vehicle is driven, determining whether a high-frequency component is included in the voltage profile in the frequency domain based on the current profile, converting the voltage profile of each battery cell from a time domain to a frequency domain when it is determined that the voltage profile in the frequency domain includes a high-frequency component, determining frequency coefficients of each battery cell, and diagnosing an abnormality in each battery cell of which the relative comparison value exceeds a threshold.

Yet another aspect of the present disclosure provides an apparatus for diagnosing an abnormality of a battery cell configured for preventing thermal runaway of the battery cell in advance while driving a vehicle by repeatedly generating a current profile and a voltage profile of each battery cell while the vehicle is driven, determining whether a high-frequency component is included in the voltage profile in the frequency domain based on the current profile, converting the voltage profile of each battery cell from a time domain to a frequency domain when it is determined that the voltage profile in the frequency domain includes a high-frequency component, determining relative comparison values of frequency coefficients of each battery cell, diagnosing that an abnormality occurs in the battery cell detected as the number of relative comparison values exceeding a threshold exceeds a preset number of times.

Yet another aspect of the present disclosure provides an apparatus for diagnosing an abnormality of a battery cell configured for preventing thermal runaway of the battery cell in advance while driving a vehicle by generating a current profile and a voltage profile of each battery cell every time the vehicle is driven, determining whether a high-frequency component is included in the voltage profile in the frequency domain based on the current profile, converting the voltage profile of each battery cell from a time domain to a frequency domain when it is determined that the voltage profile in the frequency domain includes a high-frequency component, determining relative comparison values of frequency coefficients of each battery cell, recording an identification number of a battery cell corresponding to the maximum value among relative comparison values and an identification number of a battery cell corresponding to the minimum value among relative comparison values, and diagnosing that an abnormality occurs in a battery cell with an identification number recorded in excess of a preset number of times.

The technical problems to be solved by the present disclosure are not limited to the aforementioned problems, and any other technical problems not mentioned herein will be clearly understood from the following description by those skilled in the art to which the present disclosure pertains. Also, it may be easily understood that the objects and advantages of the present disclosure may be realized by the units and combinations thereof recited in the claims.

According to an aspect of the present disclosure, an apparatus for diagnosing an abnormality in a battery cell includes a battery including a plurality of battery cells, a controller that generates a voltage profile of each of the battery cells when a vehicle is driven, converts the voltage profile of each of the battery cells from a time domain to a frequency domain, determines a frequency coefficient of each of the battery cells, and diagnoses an abnormality in each of the battery cells based on a relative comparison value of the frequency coefficient between the plurality of battery cells.

According to an exemplary embodiment of the present disclosure, the controller may be configured to determine relative comparison values for each frequency for each of the battery cells, and conclude that an abnormality occurs in a battery cell for which a relative comparison value exceeding a threshold is detected among the relative comparison values.

According to an exemplary embodiment of the present disclosure, the controller may be configured to determine relative comparison values for each frequency for each battery cell a number of times, and conclude that an abnormality occurs in a battery cell detected as a number of relative comparison values exceeding a threshold among the relative comparison values for each frequency exceeds a preset number of times.

According to an exemplary embodiment of the present disclosure, the controller may be configured to determine relative comparison values for each frequency of each battery cell every time the vehicle is driven, record an identification number of a battery cell corresponding to a maximum value and an identification number of a battery cell corresponding to a minimum value among the relative comparison values, and conclude that an abnormality occurs in a battery cell with an identification number recorded in excess of a preset number of times.

According to an exemplary embodiment of the present disclosure, the controller may conclude that an abnormality occurs in a battery cell detected as a number of maximum values among the relative comparison values exceeds a preset number of times.

According to an exemplary embodiment of the present disclosure, the controller may conclude that an abnormality occurs in a battery cell detected as a number of minimum values among the relative comparison values exceeds a preset number of times.

According to an exemplary embodiment of the present disclosure, the controller may further generate a current profile of each battery cell when the vehicle is driven, determine whether a high-frequency component is included in the voltage profile in the frequency domain based on the current profile, and diagnose an abnormality in each battery cell when it is determined that the voltage profile in the frequency domain includes the high-frequency component,

According to an exemplary embodiment of the present disclosure, the controller may be configured to conclude that the voltage profile in the frequency domain includes the high-frequency component when a variance of a current value exceeds a first threshold and an integrated value of an absolute value of an amount of current change exceeds a second threshold in a load state for a preset time.

According to an exemplary embodiment of the present disclosure, the controller may be configured to conclude that the voltage profile in the frequency domain includes the high-frequency component when a variance of a current value exceeds a first threshold in a load state for a preset time.

According to an exemplary embodiment of the present disclosure, the controller may be configured to conclude that the voltage profile in the frequency domain includes the high-frequency component when the integrated value of the absolute value of the amount of current change exceeds a second threshold in a load state for a preset time.

According to another aspect of the present disclosure, a method of diagnosing an abnormality in a battery cell includes generating, by a controller, a voltage profile of each of battery cells when a vehicle including the plurality of battery cells is driven, converting, by the controller, the voltage profile of each of the battery cells from a time domain to a frequency domain, determining, by the controller, a frequency coefficient of each of the battery cells, and diagnosing, by the controller, an abnormality in each of the battery cells based on a relative comparison value of the frequency coefficient between the plurality of battery cells.

According to an exemplary embodiment of the present disclosure, the diagnosing of the abnormality in each of the battery cells may include determining, by the controller, relative comparison values for each frequency for each of the battery cells, and concluding, by the controller, that an abnormality occurs in a battery cell for which a relative comparison value exceeding a threshold is detected among the relative comparison values.

According to an exemplary embodiment of the present disclosure, the diagnosing of the abnormality in each of the battery cells may include determining, by the controller, relative comparison values for each frequency for each battery cell a number of times, and concluding, by the controller, that an abnormality occurs in a battery cell detected as a number of relative comparison values exceeding a threshold among the relative comparison values for each frequency exceeds a preset number of times.

According to an exemplary embodiment of the present disclosure, the diagnosing of the abnormality in each of the battery cells may include determining, by the controller, relative comparison values for each frequency of each battery cell every time the vehicle is driven, recording, by the controller, an identification number of a battery cell corresponding to a maximum value and an identification number of a battery cell corresponding to a minimum value among the relative comparison values, and concluding, by the controller, that an abnormality occurs in a battery cell with an identification number recorded in excess of a preset number of times.

According to an exemplary embodiment of the present disclosure, the diagnosing of the abnormality in the battery cell with the identification number may include concluding, by the controller, that an abnormality occurs in a battery cell detected as a number of maximum values among the relative comparison values exceeds a preset number of times.

According to an exemplary embodiment of the present disclosure, the diagnosing of the abnormality in the battery cell with the identification number may include concluding, by the controller, that an abnormality occurs in a battery cell detected as a number of minimum values among the relative comparison values exceeds a preset number of times.

According to an exemplary embodiment of the present disclosure, the generating of the voltage profile of each of the battery cells may further include generating, by the controller, a current profile of each battery cell when the vehicle is driven, and determining, by the controller, whether a high-frequency component is included in the voltage profile in the frequency domain based on the current profile.

According to an exemplary embodiment of the present disclosure, the determining of whether the high-frequency component is included in the voltage profile may include concluding, by the controller, that the voltage profile in the frequency domain includes the high-frequency component when a variance of a current value exceeds a first threshold and an integrated value of an absolute value of an amount of current change exceeds a second threshold in a load state for a preset time.

According to an exemplary embodiment of the present disclosure, the determining of whether the high-frequency component is included in the voltage profile may include concluding, by the controller, that the voltage profile in the frequency domain includes the high-frequency component when a variance of a current value exceeds a first threshold in a load state for a preset time.

According to an exemplary embodiment of the present disclosure, the determining of whether the high-frequency component is included in the voltage profile may include concluding, by the controller, that the voltage profile in the frequency domain includes the high-frequency component when the integrated value of the absolute value of the amount of current change exceeds a second threshold in a load state for a preset time.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram illustrating a configuration of an apparatus for diagnosing an abnormality in a battery cell according to an exemplary embodiment of the present disclosure;

FIG. 2 is diagram illustrating an example of a result of converting the voltage profile of a battery cell from the time domain to the frequency domain by a controller provided in an apparatus for diagnosing an abnormality in a battery cell according to an exemplary embodiment of the present disclosure;

FIG. 3 is a diagram illustrating a process for determining a frequency coefficient of a battery cell by a controller provided in an apparatus for diagnosing an abnormality in a battery cell according to an exemplary embodiment of the present disclosure;

FIG. 4 is a diagram illustrating a process for determining frequency coefficients of a plurality of battery cells by a controller provided in an apparatus for diagnosing an abnormality in a battery cell according to an exemplary embodiment of the present disclosure;

FIG. 5 is a diagram illustrating a process for determining relative comparison values of frequency coefficients for a plurality of battery cells by a controller provided in an apparatus for diagnosing an abnormality in a battery cell according to an exemplary embodiment of the present disclosure;

FIG. 6 is a diagram illustrating an example of an identification number of each battery cell recorded for each trip by a controller provided in an apparatus for diagnosing an abnormality in a battery cell according to an exemplary embodiment of the present disclosure;

FIG. 7 is a flowchart illustrating a method of diagnosing an abnormality in a battery cell according to an exemplary embodiment of the present disclosure; and

FIG. 8 is a block diagram illustrating a determining system for executing a method of diagnosing an abnormality in a battery cell according to various exemplary embodiments of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the exemplary drawings. In adding the reference numerals to the components of each drawing, it should be noted that the identical or equivalent component is designated by the identical numeral even when they are displayed on other drawings. Furthermore, in describing the exemplary embodiment of the present disclosure, a detailed description of the related known configuration or function will be omitted when it is determined that it interferes with the understanding of the exemplary embodiment of the present disclosure.

Furthermore, terms, such as first, second, A, B, (a), (b) or the like may be used herein when describing components of the present disclosure. The terms are provided only to distinguish the elements from other elements, and the essences, sequences, orders, and numbers of the elements are not limited by the terms. Furthermore, unless defined otherwise, all terms used herein, including technical or scientific terms, include the same meanings as those generally understood by those skilled in the art to which the present disclosure pertains. The terms defined in the generally used dictionaries should be construed as including the meanings that coincide with the meanings of the contexts of the related technologies, and should not be construed as ideal or excessively formal meanings unless clearly defined in the specification of the present disclosure.

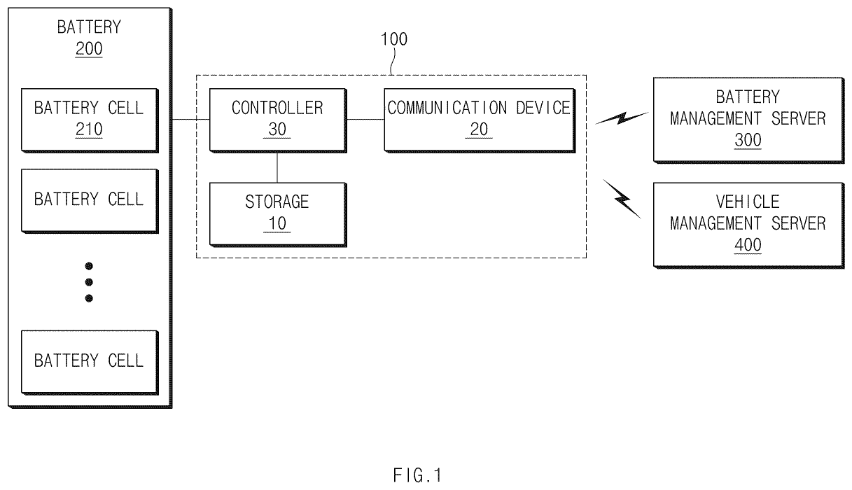

FIG. 1 is a block diagram illustrating a configuration of an apparatus for diagnosing an abnormality in a battery cell according to an exemplary embodiment of the present disclosure.

As shown in FIG. 1, an apparatus 100 for diagnosing an abnormality in a battery cell may include storage 10, a communication device 20, and a controller 30. In the instant case, depending on a scheme of implementing the apparatus 100 for diagnosing an abnormality in a battery cell according to an exemplary embodiment of the present disclosure, components may be combined with each other to be implemented as one, or some components may be omitted. For example, the apparatus 100 for diagnosing an abnormality in a battery cell may be implemented within a battery management system (BMS), or the BMS may be implemented to perform functions of the apparatus 100 for diagnosing an abnormality in a battery cell.

Regarding each component, the storage 10 may store various logic, algorithms and programs required in the processes of generating a voltage profile of each battery cell 210 while the vehicle is driven, converting the voltage profile of each battery cell 210 from a time domain to a frequency domain, determining a frequency coefficient of each battery cell 210, and diagnosing an abnormality in each battery cell 210 based on relative comparison values of the frequency coefficients between the battery cells 210. The storage 10 may store the diagnosis results of the controller 30.

In addition, the storage 10 may store various logic, algorithms and programs required in the processes of generating a voltage profile of each battery cell 210 while the vehicle is driven, converting the voltage profile of each battery cell 210 from a time domain to a frequency domain, determining relative comparison values for frequency coefficients of each battery cell 210, and diagnosing that an abnormality occurs in the battery cell 210 of which the relative comparison value exceeds a threshold.

In addition, the storage 10 may store various logic, algorithms and programs required in the processes of repeatedly generating a voltage profile of each battery cell 210 while the vehicle is driven, converting the voltage profile of each battery cell 210 from a time domain to a frequency domain, determining relative comparison values for frequency coefficients of each battery cell 210, and diagnosing that an abnormality occurs in the battery cell 210 detected as the number of relative comparison values exceeding a threshold exceeds a preset number of times.

In addition, the storage 10 may store various logic, algorithms and programs required in the processes of generating a voltage profile of each battery cell 210 every time the vehicle is driven, converting the voltage profile of each battery cell 210 from a time domain to a frequency domain, determining relative comparison values for frequency coefficients of each battery cell 210, recording an identification number of a battery cell corresponding to the maximum value among the relative comparison values and an identification number of a battery cell corresponding to the minimum value among the relative comparison values, and diagnosing that an abnormality occurs in a battery cell with an identification number recorded in excess of a preset number of times.

In addition, the storage 10 may store various logic, algorithms and programs required in the processes of generating a current profile and a voltage profile of each battery cell 210 while the vehicle is driven, determining whether a high-frequency component is included in the voltage profile in the frequency domain based on the current profile, converting the voltage profile of each battery cell 210 from a time domain to a frequency domain when it is determined that the voltage profile in the frequency domain includes a high-frequency component, determining frequency coefficients of each battery cell 210, and diagnosing an abnormality in each battery cell 210 based on relative comparison values of the frequency coefficients between the battery cells 210. The storage 10 may store the diagnosis results of the controller 30.

In addition, the storage 10 may store various logic, algorithms and programs required in the processes of generating a current profile and a voltage profile of each battery cell 210 while the vehicle is driven, determining whether a high-frequency component is included in the voltage profile in the frequency domain based on the current profile, converting the voltage profile of each battery cell 210 from a time domain to a frequency domain when it is determined that the voltage profile in the frequency domain includes a high-frequency component, determining relative comparison values of frequency coefficients of each battery cell 210, and diagnosing an abnormality in each battery cell 210 of which the relative comparison value exceeds a threshold.

In addition, the storage 10 may store various logic, algorithms and programs required in the processes of repeatedly generating a current profile and a voltage profile of each battery cell 210 while the vehicle is driven, determining whether a high-frequency component is included in the voltage profile in the frequency domain based on the current profile, converting the voltage profile of each battery cell 210 from a time domain to a frequency domain when it is determined that the voltage profile in the frequency domain includes a high-frequency component, determining relative comparison values of frequency coefficients of each battery cell 210, and diagnosing that an abnormality occurs in the battery cell 210 detected as the number of relative comparison values exceeding a threshold exceeds a preset number of times.

In addition, the storage 10 may store various logic, algorithms and programs required in the processes of generating a current profile and a voltage profile of each battery cell 210 every time the vehicle is driven, determining whether a high-frequency component is included in the voltage profile in the frequency domain based on the current profile, converting the voltage profile of each battery cell 210 from a time domain to a frequency domain when it is determined that the voltage profile in the frequency domain includes a high-frequency component, determining relative comparison values of frequency coefficients of each battery cell 210, recording an identification number of a battery cell corresponding to the maximum value among the relative comparison values and an identification number of a battery cell corresponding to the minimum value among the relative comparison values, and diagnosing that an abnormality occurs in a battery cell with an identification number recorded in excess of a preset number of times.

The communication device 20, which is a module that provides a communication interface with a battery management server 300 or a vehicle management server 400, transmits the results diagnosed by the controller 30 to the battery management server 300 or the vehicle management server. For example, the communication device 20 may transmit a message including information related to the battery cell 210 diagnosed as an abnormality to the battery management server 300 or the vehicle management server 400. The communication device 20 may include at least one of a mobile communication module, a wireless Internet module, and a short-range communication module.

The mobile communication module may communicate with the battery management server 300 or the vehicle management server 400 through a mobile communication network constructed according to a technical standard or communication scheme for mobile communication (e.g., Global System for Mobile communication (GSM), Code Division Multi Access (CDMA), code division multi access 2000 (CDMA2000), enhanced voice-data optimized or enhanced voice-data only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTEA), and the like).

The wireless Internet module, which is a module for wireless Internet access, may communicate with the battery management server 300 or the vehicle management server 400 through wireless LAN (WLAN), wireless-fidelity (Wi-Fi), Wi-Fi direct, Digital Living Network Alliance (DLNA), Wireless Broadband (WiBro), Worldwide Interoperability for Microwave Access (WiMAX), High Speed Downlink Packet Access (HSDPA), High Speed Uplink Packet Access (HSUPA), Long Term Evolution (LTE), Long Term Evolution-Advanced (LTE-A), and the like.

The short-range communication module may support short-range communication with the battery management server 300 or the vehicle management server 400 by use of at least one of Bluetooth™, radio frequency identification (RFID), infrared data association (IrDA), ultra wideband (UWB), ZigBee, Near Field Communication (NFC), and wireless universal serial bus (USB) technology.

The battery management server 300 may receive diagnostic results from the apparatus 100 for diagnosing an abnormality of the battery cells provided in each vehicle, and may manage the status of the battery cells provided in each vehicle. The vehicle management server 400 may receive diagnostic results from the apparatus 100 for diagnosing an abnormality of the battery cells provided in each vehicle, and may manage the status of each vehicle.

The controller 30 may be electrically connected to each component and may perform overall control so that each component is configured to perform its function. The controller 30 may be implemented in a form of hardware or software, or may be implemented in a combination of hardware and software. The controller 30 may be implemented as a microprocessor, but is not limited thereto.

The controller 30 may be configured to generate a voltage profile of each battery cell 210 while the vehicle is driven, convert the voltage profile of each battery cell 210 from a time domain to a frequency domain, determine a frequency coefficient of each battery cell 210, and diagnose an abnormality in each battery cell 210 based on relative comparison values of the frequency coefficients between the battery cells 210. In the instant case, the controller 30 may be configured to generate the voltage profile of each battery cell 210 in preset time units (e.g., 10 seconds) while the vehicle is driven.

The controller 30 may be configured to alert a user via a cluster in the vehicle when an abnormality occurs in each battery cell 210.

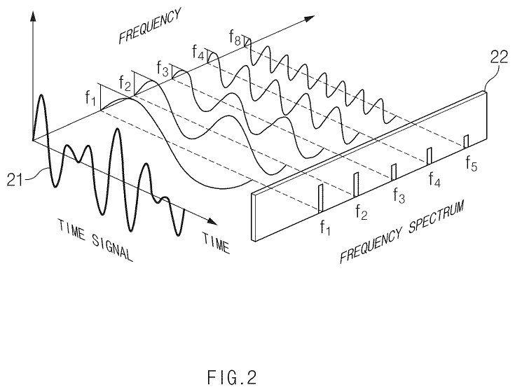

Hereinafter, the operation of the controller 30 will be described with reference to FIGS. 2 to 6.

FIG. 2 is diagram illustrating an example of a result of converting the voltage profile of a battery cell from the time domain to the frequency domain by a controller provided in an apparatus for diagnosing an abnormality in a battery cell according to an exemplary embodiment of the present disclosure.

As shown in FIG. 2, the controller 30 may convert a voltage profile 21 in the time domain into a voltage profile 22 in the frequency domain. In the instant case, the voltage profile 22 in the frequency domain may include a plurality of predetermined frequency components f₀, f₁, f₂, f₃, f₄, and f₅, but among the high frequency components, f₁, f₂, f₃ include the greatest influence on diagnosing an abnormality in the battery cell 210. That is, the controller 30 may check whether the voltage of a predetermined battery cell 210 is significantly smaller or greater than those of other battery cells 210 at f₁, f₂ and f₃ in the frequency domain. This is not observed in the time domain.

In the instant case, the controller 30 may convert the voltage profile 21 in the time domain to the voltage profile 21 in the frequency domain based on one of a Fourier transform (FT) algorithm, a Fast Fourier Transform (FFT) algorithm, a nonlinear frequency response analysis (NFRA) algorithm, and a Wavelet transform (WT) algorithm.

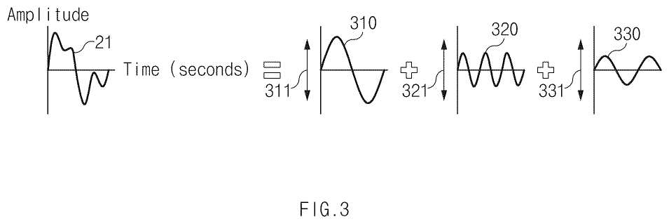

FIG. 3 is a diagram illustrating a process for determining a frequency coefficient of a battery cell by a controller provided in an apparatus for diagnosing an abnormality in a battery cell according to an exemplary embodiment of the present disclosure.

In FIG. 3, reference numeral 310 represents the sine waveform of the high-frequency component f₁, reference numeral 311 represents the frequency coefficient of the high-frequency component f₁, reference numeral 320 represents the sine waveform of the high-frequency component f₂, reference numeral 321 represents the frequency coefficient of the high-frequency component f₂, reference numeral 330 represents the sine waveform of the high-frequency component f₃, and reference numeral 331 represents the frequency coefficient of the high-frequency component f₃. In the instant case, the frequency coefficient means the amplitude of a sine wave.

As shown in FIG. 3, the voltage profile 21 in the time domain may be expressed in a form of the sum of f₁ 310, f₂ 320 and f; 330 which are high frequency components in the frequency domain. Accordingly, the controller 30 may be configured to determine the frequency coefficient of f₁ 310, the frequency coefficient of f₂ 320, and the frequency coefficient of f₃ 330 for each battery cell 210.

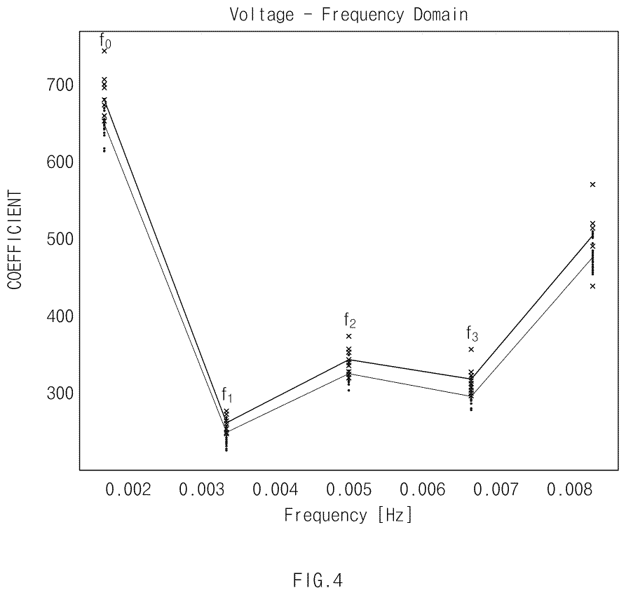

FIG. 4 is a diagram illustrating a process for determining frequency coefficients of a plurality of battery cells by a controller provided in an apparatus for diagnosing an abnormality in a battery cell according to an exemplary embodiment of the present disclosure.

In FIG. 4, f₀ is a direct current (DC) component that only represents the difference between the voltages of each battery cell 210 and is not used to diagnose abnormalities in each battery cell 210. Except for the frequency coefficient of f₀, the remaining frequency coefficients of f₁, f₂ and f₃ may be used to diagnose abnormalities in each battery cell 210.

For example, when a battery 200 is implemented with a first battery cell, a second battery cell, and a third battery cell, the controller 30 may select f₁, f₂ and f₃ among the high frequency components of the first battery cell and determine the frequency coefficient of f₁, the frequency coefficient of f₂, and the frequency coefficient of f₃. The controller 30 may select f₁, f₂ and f₃ among the high frequency components of the second battery cell and determine the frequency coefficient of f₁, the frequency coefficient of f₂, and the frequency coefficient of f₃. In addition, the controller 30 may select f₁, f₂ and f₃ among the high frequency components of the third battery cell and determine the frequency coefficient of f₁, the frequency coefficient of f₂, and the frequency coefficient of f₃.

Therefore, as shown in FIG. 4, the frequency coefficient of f₁ includes the frequency coefficient of f₁ of the first battery cell, the frequency coefficient of f₁ of the second battery cell, and the frequency coefficient of f₁ of the third battery cell. The frequency coefficient of f₂ includes the frequency coefficient of f₂ of the first battery cell, the frequency coefficient of f₂ of the second battery cell, and the frequency coefficient of f₂ of the third battery cell. Furthermore, the frequency coefficient of f₃ includes the frequency coefficient of f₃ of the first battery cell, the frequency coefficient of f₃ of the second battery cell, and the frequency coefficient of f₃ of the third battery cell.

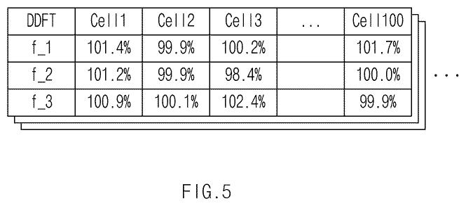

FIG. 5 is a diagram illustrating a process for determining relative comparison values of frequency coefficients for a plurality of battery cells by a controller provided in an apparatus for diagnosing an abnormality in a battery cell according to an exemplary embodiment of the present disclosure.

As shown in FIG. 5, a relative comparison value DDFT determined by the controller 30 for Cell 1 may include 101.4% of the relative comparison value of f₁, 101.2% of the relative comparison value of f₂, and 100.9% of the relative comparison value of f₃. Furthermore, the relative comparison value determined by the controller 30 for Cell 2 may include 99.9% of the relative comparison value of f₁, 99.9% of the relative comparison value of f₂, and 99.9% of the relative comparison value of f₃. Furthermore, the relative comparison value determined by the controller 30 for Cell 3 may include 100.2% of the relative comparison value of f₁, 98.4% of the relative comparison value of f₂, and 102.4% of the relative comparison value of f₃. Furthermore, the relative comparison value determined by the controller 30 for Cell 100 may include 101.7% of the relative comparison value of f₁, 100.0% of the relative comparison value of f₂, and 99.9% of the relative comparison value of f₃. In the instant case, the controller 30 may repeatedly generate a table as shown in FIG. 5 while the vehicle is driven. In the instant case, one table represents the DDFT for the voltage profile of each battery cell for 10 seconds.

Meanwhile, for example, the controller 30 may be configured to determine the relative comparison value DDFT based on following Equation 1.

$$DDFT = \frac{{C}_{T}}{{C}_{A}} \times 100 \qquad [ Equation 1 ]$$

Where CA represents the average of the frequency coefficients for each frequency component, and CT represents the target frequency coefficient of each frequency component.

For example, because CA is 210 when the frequency coefficient of f₁, which is the high frequency component of the first battery cell, is 200, the frequency coefficient of f₁, which is the high frequency component of the second battery cell, is 230, and the frequency coefficient of f₁, which is the high frequency component of the third battery cell, is 200, the DDFT for f₁ of the first battery cell is 95.2%, the DDFT for f₁ of the second battery cell is 109.5%, and the DDFT for f₁ of the third battery cell is 95.2%.

As an exemplary embodiment of the present disclosure, because CA is 220 when the frequency coefficient of f₂, which is the high frequency component of the first battery cell, is 210, the frequency coefficient of f₂, which is the high frequency component of the second battery cell, is 230, and the frequency coefficient of f₂, which is the high frequency component of the third battery cell, is 220, the DDFT for f₂ of the first battery cell is 95.4%, the DDFT for f₂ of the second battery cell is 104.5%, and the DDFT for f₂ of the third battery cell is 100.0%.

In the instant case, the controller 30 may further generate a current profile of each battery cell while the vehicle is driven, determine whether a high-frequency component is included in the voltage profile in the frequency domain based on the current profile, and initiate a process of diagnosing an abnormality in each battery cell 210 when it is determined that the voltage profile in the frequency domain includes a high-frequency component.

In the instant case, when it is not in a no-load (OA) state for a preset time (e.g., 10 seconds), the variance of the current value for 10 seconds exceeds a threshold (e.g., a), and the integration result of the absolute value of the current change for 10 seconds exceeds a threshold (e.g., B), the controller 30 may initiate a process of diagnosing an abnormality in each battery cell 210.

Furthermore, when it is not in a no-load (OA) state for a preset time (e.g., 10 seconds) and the variance of the current value for 10 seconds exceeds a threshold (e.g., a), the controller 30 may initiate a process of diagnosing an abnormality in each battery cell 210.

Furthermore, when it is not in a no-load (OA) state for a preset time (e.g., 10 seconds) and the integration result of the absolute value of the current change for 10 seconds exceeds a threshold (e.g., B), the controller 30 may initiate a process of diagnosing an abnormality in each battery cell 210.

Meanwhile, as shown in FIG. 5, in a state in which the relative comparison value for each high-frequency component of each battery cell 210 is determined, the controller 30 may diagnose whether each battery cell 210 is abnormal in various manners as follows.

As various exemplary embodiments of the present disclosure, the controller 30 may diagnose that an abnormality occurs in the battery cell 210 for which a relative comparison value exceeding a threshold is detected among the relative comparison values for each high-frequency component.

For example, when the threshold is set to 101.5%, the controller 30 may diagnose that an abnormality occurs in Cell 100 in FIG. 5.

As various exemplary embodiments of the present disclosure, the controller 30 may diagnose that an abnormality occurs in the battery cell 210 detected as the number of relative comparison values exceeding a threshold exceeds a preset number of times.

For example, as shown in FIG. 5, when 10 relative comparison values for each high-frequency component of each battery cell 201 are generated in units of 10 seconds, and the battery cell which is detected as the number of relative comparison values exceeding a threshold exceeds a preset number of times, is Cell 1, the controller 30 may diagnose that an abnormality occurs in Cell 1.

As various exemplary embodiments of the present disclosure, the controller 30 may be configured to determine the relative comparison value of the frequency coefficient for each high-frequency component of each battery cell 210 every time the vehicle is driven (by trip), record an identification number of a battery cell corresponding to the maximum value and an identification number of a battery cell corresponding to the minimum value among relative comparison values for each high-frequency component, and diagnose that an abnormality occurs in a battery cell with an identification number recorded in excess of a preset number of times. In the instant case, the controller 30 may perform a process of determining relative comparison values of frequency coefficients for each high-frequency component of each battery cell 210 at least once while the vehicle is driven.

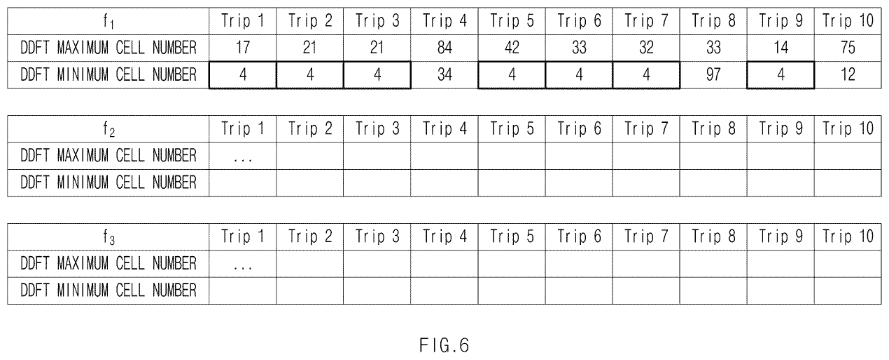

FIG. 6 is a diagram illustrating an example of the identification number of each battery cell recorded for each trip by a controller provided in an apparatus for diagnosing an abnormality in a battery cell according to an exemplary embodiment of the present disclosure.

In Trip 1, the battery cell in which the maximum relative comparison value is detected is battery cell No. 17, and the battery cell in which the minimum relative comparison value is detected is battery cell No. 4. In the instant case, the trip indicates the time from when the vehicle starts driving to when the vehicle ends driving (ignition off).

In Trip 2, the battery cell in which the maximum relative comparison value is detected is battery cell No. 21, and the battery cell in which the minimum relative comparison value is detected is battery cell No. 4.

In Trip 3, the battery cell in which the maximum relative comparison value is detected is battery cell No. 21, and the battery cell in which the minimum relative comparison value is detected is battery cell No. 4.

In Trip 4, the battery cell in which the maximum relative comparison value is detected is battery cell No. 84, and the battery cell in which the minimum relative comparison value is detected is battery cell No. 34.

In Trip 5, the battery cell in which the maximum relative comparison value is detected is battery cell No. 42, and the battery cell in which the minimum relative comparison value is detected is battery cell No. 4.

In Trip 6, the battery cell in which the maximum relative comparison value is detected is battery cell No. 33, and the battery cell in which the minimum relative comparison value is detected is battery cell No. 4.

In Trip 7, the battery cell in which the maximum relative comparison value is detected is battery cell No. 32, and the battery cell in which the minimum relative comparison value is detected is battery cell No. 4.

In Trip 8, the battery cell in which the maximum relative comparison value is detected is battery cell No. 33, and the battery cell in which the minimum relative comparison value is detected is battery cell No. 97.

In Trip 9, the battery cell in which the maximum relative comparison value is detected is battery cell No. 14, and the battery cell in which the minimum relative comparison value is detected is battery cell No. 4.

In Trip 10, the battery cell in which the maximum relative comparison value is detected is battery cell No. 75, and the battery cell in which the minimum relative comparison value is detected is battery cell No. 12.

As shown in FIG. 6, it may be understood that the battery cell of No. 4 is recorded 7 times as a result of recording the identification numbers of the battery cell with the maximum relative comparison value and the identification numbers of the battery cell with the minimum relative comparison value for 10 trips by the controller 30. Accordingly, the controller 30 may diagnose that an abnormality occurs in the battery cell of No. 4.

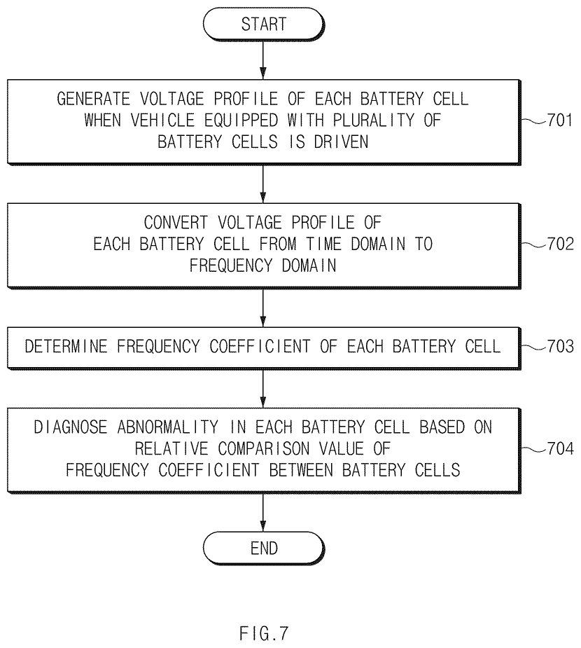

FIG. 7 is a flowchart illustrating a method of diagnosing an abnormality in a battery cell according to an exemplary embodiment of the present disclosure.

First, when a vehicle provided with the plurality of battery cells 210 is driven, the controller 30 may be configured to generate a voltage profile of each battery cell 210 in 701.

Accordingly, the controller 30 may convert the voltage profile of each battery cell 210 from a time domain to a frequency domain in 702.

Accordingly, the controller 30 may be configured to determine the frequency coefficient of each battery cell 210 in 703.

Accordingly, the controller 30 may diagnose an abnormality in each battery cell 210 based on the relative comparison values of the frequency coefficients between the battery cells 210 in 704.

Accordingly, the controller 30 may alert a user via a cluster in the vehicle in response that the abnormality occurs in each battery cell 210. The controller 30 may turn on warning light in the vehicle in response that the abnormality occurs in each battery cell 210. The controller 30 may limit an amount of charge or discharge of the battery 200 (that is, a power of the vehicle) in response that the abnormality occurs in each battery cell 210. The controller 30 may control a driving strategy of the vehicle in response that the abnormality occurs in each battery cell 210.

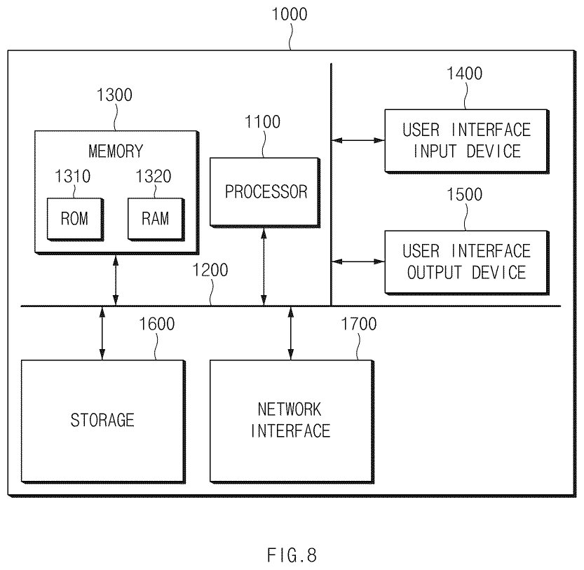

FIG. 8 is a block diagram illustrating a computing system for executing a method of diagnosing an abnormality in a battery cell according to various exemplary embodiments of the present disclosure.

Referring to FIG. 8, a method of diagnosing an abnormality in a battery cell according to an exemplary embodiment of the present disclosure described above may be implemented through a computing system 1000. The computing system 1000 may include at least one processor 1100, a memory 1300, a user interface input device 1400, a user interface output device 1500, storage 1600, and a network interface 1700 connected through a system bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a Read-Only Memory (ROM) 1310 and a Random Access Memory (RAM) 1320.

Accordingly, the processes of the method or algorithm described in relation to the exemplary embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, solid state drive (SSD), a detachable disk, or a CD-ROM. The exemplary storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor 1100 and the storage medium may reside in the user terminal as an individual component.

The control device may be at least one microprocessor operated by a predetermined program which may include a series of commands for carrying out the method included in the aforementioned various exemplary embodiments of the present disclosure.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for diagnosing an abnormality in a battery cell, the apparatus comprising:
a battery including a plurality of battery cells;
a controller configured to:
generate a voltage profile of each of the battery cells in response that a vehicle is driven,
convert the voltage profile of each of the battery cells from a time domain to a frequency domain,
determine a frequency coefficient of each of the battery cells based on the frequency domain, and
diagnose an abnormality in each of the battery cells based on a relative comparison value of the frequency coefficient between the plurality of battery cells.

2. The apparatus of claim 1, wherein the controller is further configured to:
determine relative comparison values for each frequency for each of the battery cells, and
conclude that an abnormality occurs in a battery cell for which a relative comparison value exceeding a threshold among the battery cells is detected among the relative comparison values.

3. The apparatus of claim 1, wherein the controller is further configured to:
determine relative comparison values for each frequency for each battery cell a number of times, and
conclude that an abnormality occurs in a battery cell detected among the battery cells as a number of relative comparison values exceeding a threshold among the relative comparison values for each frequency exceeds a preset number of times.

4. The apparatus of claim 1, wherein the controller is further configured to:
determine relative comparison values for each frequency of each battery cell every time the vehicle is driven,
record an identification number of a battery cell corresponding to a maximum value and an identification number of a battery cell corresponding to a minimum value among the relative comparison values, and
conclude that an abnormality occurs in a battery cell with an identification number recorded in excess of a preset number of times among the battery cells.

5. The apparatus of claim 4, wherein the controller is further configured to conclude that an abnormality occurs in a battery cell detected among the battery cells as a number of maximum values among the relative comparison values exceeds a preset number of times.

6. The apparatus of claim 4, wherein the controller is further configured to conclude that an abnormality occurs in a battery cell detected among the battery cells as a number of minimum values among the relative comparison values exceeds a preset number of times.

7. The apparatus of claim 1, wherein the controller is further configured to:
generate a current profile of each battery cell in response that the vehicle is driven,
determine whether a high-frequency component is included in the voltage profile in the frequency domain based on the current profile, and
conclude an abnormality in each battery cell in response that the controller concludes that the voltage profile in the frequency domain includes the high-frequency component.

8. The apparatus of claim 7, wherein the controller is further configured to conclude that the voltage profile in the frequency domain includes the high-frequency component in response that a variance of a current value exceeds a first threshold and an integrated value of an absolute value of an amount of current change exceeds a second threshold in a load state for a preset time.

9. The apparatus of claim 7, wherein the controller is further configured to conclude that the voltage profile in the frequency domain includes the high-frequency component in response that a variance of a current value exceeds a first threshold in a load state for a preset time.

10. The apparatus of claim 7, wherein the controller is further configured to conclude that the voltage profile in the frequency domain includes the high-frequency component in response that the integrated value of the absolute value of the amount of current change exceeds a second threshold in a load state for a preset time.

11. A method of diagnosing an abnormality in a battery cell, the method comprising:
generating, by a controller, a voltage profile of each of battery cells in response that a vehicle including the plurality of battery cells is driven;
converting, by the controller, the voltage profile of each of the battery cells from a time domain to a frequency domain;
determining, by the controller, a frequency coefficient of each of the battery cells, based on the frequency domain; and
diagnosing, by the controller, an abnormality in each of the battery cells based on a relative comparison value of the frequency coefficient between the plurality of battery cells.

12. The method of claim 11, wherein the diagnosing of the abnormality in each of the battery cells includes:
determining, by the controller, relative comparison values for each frequency for each of the battery cells; and
concluding, by the controller, that an abnormality occurs in a battery cell for which a relative comparison value exceeding a threshold is detected among the relative comparison values.

13. The method of claim 11, wherein the diagnosing of the abnormality in each of the battery cells includes:
determining, by the controller, relative comparison values for each frequency for each battery cell a number of times; and
concluding, by the controller, that an abnormality occurs in a battery cell detected among the battery cells as a number of relative comparison values exceeding a threshold among the relative comparison values for each frequency exceeds a preset number of times.

14. The method of claim 11, wherein the diagnosing of the abnormality in each of the battery cells includes:
determining, by the controller, relative comparison values for each frequency of each battery cell every time the vehicle is driven;
recording, by the controller, an identification number of a battery cell corresponding to a maximum value and an identification number of a battery cell corresponding to a minimum value among the relative comparison values; and
concluding, by the controller, that an abnormality occurs in a battery cell with an identification number recorded in excess of a preset number of times among the battery cells.

15. The method of claim 14, wherein the diagnosing of the abnormality in the battery cell with the identification number includes concluding, by the controller, that an abnormality occurs in a battery cell detected as a number of maximum values among the relative comparison values exceeds a preset number of times among the battery cells.

16. The method of claim 14, wherein the diagnosing of the abnormality in the battery cell with the identification number includes concluding, by the controller, that an abnormality occurs in a battery cell detected, among the battery cells, as a number of minimum values among the relative comparison values exceeds a preset number of times.

17. The method of claim 11, wherein the generating of the voltage profile of each of the battery cells further includes:
generating, by the controller, a current profile of each battery cell in response that the vehicle is driven; and
determining, by the controller, whether a high-frequency component is included in the voltage profile in the frequency domain based on the current profile.

18. The method of claim 17, wherein the determining of whether the high-frequency component is included in the voltage profile includes concluding, by the controller, that the voltage profile in the frequency domain includes the high-frequency component in response that a variance of a current value exceeds a first threshold and an integrated value of an absolute value of an amount of current change exceeds a second threshold in a load state for a preset time.

19. The method of claim 17, wherein the determining of whether the high-frequency component is included in the voltage profile includes concluding, by the controller, that the voltage profile in the frequency domain includes the high-frequency component in response that a variance of a current value exceeds a first threshold in a load state for a preset time.

20. The method of claim 17, wherein the determining of whether the high-frequency component is included in the voltage profile includes concluding, by the controller, that the voltage profile in the frequency domain includes the high-frequency component in response that the integrated value of the absolute value of the amount of current change exceeds a second threshold in a load state for a preset time.
